(19) United States
(12) Patent Application Publication
(10) Pub. No.: US 2026/0114230 A1
(43) Pub. Date: Apr. 23, 2026

(54) SUBSTRATE SUPPORT, SUBSTRATE PROCESSING APPARATUS, AND METHOD FOR SUPPLYING ELECTRIC POWER

(71) Applicants: THE UNIVERSITY OF TOKYO, Tokyo (JP); Tokyo Electron Limited, Tokyo (JP)

(72) Inventors: Takao OKABE, Tokyo (JP); Shinichi TANABE, Tokyo (JP); Toshikazu AKIMOTO, Tokyo (JP); Naoki UMESHITA, Tokyo (JP)

(73) Assignees: THE UNIVERSITY OF TOKYO, Tokyo (JP); Tokyo Electron Limited, Tokyo (JP)

(21) Appl. No.: 19/373,765

(22) Filed: Oct. 30, 2025

Related U.S. Application Data
(63) Continuation of application No. PCT/JP2024/016635, filed on Apr. 30, 2024.

(30) Foreign Application Priority Data
May 11, 2023 (JP) 2023-078728

(51) Int. Cl. H10P 72/72; H01J 37/32

(52) U.S. Cl. CPC H10P 72/722; H01J 37/32715; H01J 2237/2007; H01J 2237/20214

(57) ABSTRACT

A substrate support including a rotation side member and a fixation side member, in which the rotation side member includes a first stage having a support surface that supports a substrate, and at least one electrode arranged in the first stage, the fixation side member includes a second stage arranged so as to form a gap between the second stage and the first stage below the first stage, and an electric wire arranged in the second stage, and the electrode and the electric wire are electrically coupled through an ionic liquid in the gap.

### CROSS-REFERENCE TO RELATED APPLICATIONS

This application is a continuation of International Application No. PCT/JP2024/016635, filed on Apr. 30, 2024 which claims the benefit of priority of the prior Japanese Patent Application No. 2023-078728, filed on May 11, 2023, the entire contents of which are incorporated herein by reference.

### FIELD

The present disclosure relates to a substrate support, a substrate processing apparatus, and a method for supplying electric power.

### BACKGROUND

Japanese Laid-open Patent Publication No. 2015-185757 discloses a substrate support which is provided in a processing chamber for processing a substrate, has a center of a rotation axis at the center of the processing chamber, and is configured to be rotatable. A rotation mechanism that rotates the substrate support is configured as a slip ring mechanism that performs electrical connection between the rotation side and the fixation side through a metal brush or the like.

A technique according to the present disclosure is a substrate support including a rotation mechanism, in which an electrode provided inside the substrate support is supplied with electric power without mechanical contact between the rotation side and the fixation side.

### SUMMARY

In an embodiment of a present disclosure, a substrate support includes a rotation side member and a fixation side member, wherein the rotation side member includes a first stage having a support surface that supports a substrate, and at least one electrode arranged in the first stage, the fixation side member includes a second stage arranged so as to form a gap between the second stage and the first stage below the first stage, and an electric wire arranged in the second stage, and the electrode and the electric wire are electrically coupled through an ionic liquid in the gap.

### BRIEF DESCRIPTION OF DRAWINGS

FIG. 1 is a sectional view schematically illustrating a configuration example of a substrate processing system according to a first embodiment;

FIG. 2 is a sectional view schematically illustrating a configuration example of a substrate support according to the first embodiment; and

FIG. 3 is a plan view schematically illustrating a configuration example of a rotation mechanism.

### DESCRIPTION OF EMBODIMENTS

In a semiconductor production apparatus, a substrate support including a mechanism for precisely rotating a semiconductor wafer (hereinafter, referred to as a “substrate”) while holding the substrate is required. As disclosed in Japanese Laid-open Patent Publication No. 2015-185757, the rotation mechanism for rotating the substrate is configured as, for example, a slip ring mechanism in which a metal brush on a fixation side and an electrode on a rotation side are rubbed against each other for performing electrical connection between the rotation side including a substrate mounting surface and the fixation side where fixation to a processing container occurs.

However, when the electrical connection between the rotation side and the fixation side is performed using the slip ring mechanism, abrasion powder (hereinafter, referred to as “particles”) is generated by rubbing of the electrode and the metal brush, and the particles may cause failure in substrate processing. Since the electrode and the metal brush wear due to the rubbing, the slip ring mechanism needs to be replaced after a certain period of time, and the frequency of maintenance and the downtime of the semiconductor production apparatus may increase.

The present invention has been made in view of the above-described circumstances, and provides a substrate support including a rotation mechanism, in which an electrode provided inside the substrate support is supplied with electric power without mechanical contact between the rotation side and the fixation side. Hereinafter, a substrate processing apparatus including the substrate support according to the present embodiment will be described with reference to the drawings. In the present specification, elements having substantially the same functional configuration are denoted by the same reference symbol, and overlapped description thereof is avoided.

### Substrate Processing System

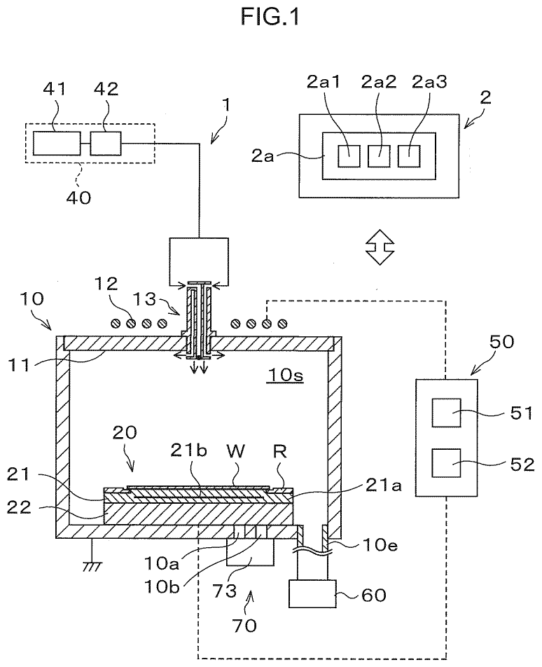

FIG. 1 is a sectional view illustrating an example of a configuration of a substrate processing system according to the present embodiment. Hereinafter, a case where the substrate processing system includes a substrate processing apparatus as a plasma processing apparatus that performs plasma processing such as a chemical vapor deposition (CVD) process or an etching process on a substrate W under vacuum (reduced pressure) will be described as an example.

The substrate processing system includes a substrate processing apparatus 1 and a controller 2. The substrate processing apparatus 1 includes a processing chamber 10, a substrate support 20, a gas supplier 40, a power supply 50, an exhauster 60, and an ionic liquid supplier 70. The substrate support 20 is arranged in the processing chamber 10. In addition, the substrate processing apparatus 1 includes a dielectric window 11, an antenna 12, and a gas inlet. The dielectric window 11 forms at least a part of a ceiling of the processing chamber 10. The antenna 12 is arranged on or above the processing chamber 10 (i.e., on or above the dielectric window 11). The processing chamber 10 has a processing space 10s defined by the dielectric window 11, the substrate support 20, and a lateral wall of the processing chamber 10. The processing chamber 10 is grounded.

The antenna 12 includes one or more coils. In an embodiment, the antenna 12 may include an outer coil and an inner coil that are coaxially arranged. In this case, an RF power supply 51 described later may be connected to both the outer coil and the inner coil, or may be connected to one of the outer coil and the inner coil.

The gas inlet is configured to introduce at least one process gas from the gas supplier 40 into the processing space 10s. In an embodiment, the gas inlet includes a center gas injector (CGI) 13. The center gas injector 13 is arranged above the substrate support 20, and mounted at a central opening formed in the dielectric window 11. The gas inlet may include, in addition to or instead of the center gas injector 13, one or more side gas injectors (SGI) mounted at one or more openings formed in a lateral wall of the processing chamber 10.

The processing chamber 10 is formed in a substantially cylindrical shape, and configured such that the inside thereof can be maintained in a vacuum (decompressed) state. The substrate support 20 described later is arranged at a substantially central part of the bottom surface of the processing chamber 10.

The substrate support 20 includes an electrostatic chuck 21 and a base 22. The electrostatic chuck 21 has one or more substrate support surfaces for supporting the substrate W to be processed. Therefore, the electrostatic chuck 21 may be configured to be capable of supporting only one substrate W or may be configured to be capable of supporting a plurality of substrates W at the same time. The electrostatic chuck 21 may further have a ring support surface (not illustrated) for supporting a ring assembly R arranged so as to surround the periphery of the substrate W in the plasma processing. The ring assembly R can include one or more edge rings and at least one covering. The base 22 supports the electrostatic chuck 21 from below. A detailed configuration of the substrate support 20 will be described later.

The gas supplier 40 may include at least one gas source 41 and at least one flow control device 42. In an embodiment, the gas supplier 40 is configured to supply at least one process gas from the corresponding gas source 41 through the corresponding flow control device 42 to the processing space 10s. Each flow control device 42 may include, for example, a mass flow controller or a flow controller of pressure control type. Further, the gas supplier 40 may include one or more flow modulation devices that modulate or pulse the flow volume of at least one process gas.

The power supply 50 includes an RF power supply 51 coupled to the processing chamber 10 through at least one impedance matching circuit. The RF power supply 51 is coupled to the antenna 12 through at least one impedance matching circuit, and is configured to supply an RF signal (RF power) for plasma production to the antenna 12. In an embodiment, the frequency of an RF signal is within the range of 10 MHz to 150 MHz. In an embodiment, the RF power supply 51 may be configured to produce a plurality of RF signals having different frequencies. One or more RF signals produced are supplied to the antenna 12. In this way, plasma is formed from at least one process gas supplied from the gas supplier 40 to the processing space 10s.

The power supply 50 may include a later-described electrode 21b arranged in the electrostatic chuck 21, and a later-described DC power supply 52 coupled to a motor 27b of a rotation mechanism 27. An electrostatic force such as a Coulomb force is generated by applying a voltage from the DC power supply 52 to the electrode 21b. By the electrostatic force generated, the substrate W is attracted to and held on the substrate support surface of the electrostatic chuck 21. Therefore, the later-described electrode 21b arranged in the electrostatic chuck 21 can be an electrostatic electrode. In addition, a voltage is applied from the DC power supply 52 to the motor 27b to rotate the rotation mechanism 27.

In the present embodiment, the power supply 50 is coupled to each of the antenna 12, the electrode 21b and the motor 27b as described above, and the RF power supply 51 coupled to the antenna 12 and the DC power supply 52 coupled to the electrode 21b and the motor 27b may be arranged independently of each other. In addition, the DC power supply for attraction of the substrate which is coupled to the electrode 21b and the DC power supply for rotation which is coupled to the motor 27b may be arranged independently of each other.

The exhauster 60 can be connected to, for example, a gas discharge port 10e provided at the bottom part of the processing chamber 10. The exhauster 60 may include a pressure adjustment valve and a vacuum pump. The pressure in the processing space 10s is adjusted by the pressure adjustment valve. The vacuum pump may include a turbomolecular pump, a dry pump, a rotary pump, or a combination thereof.

The ionic liquid supplier 70 is connected to the lower part of the processing chamber 10 through, for example, through-holes 10a and 10b formed in the bottom part of the processing chamber 10. The through-hole 10a is connected to an ionic liquid supply port 71 described later. The through-hole 10b is connected to an ionic liquid discharge port 72 described later. In addition, the ionic liquid supplier 70 includes an ionic liquid supply source 73 that stores a later-described ionic liquid L2 therein. As described later, the ionic liquid supplier 70 is configured to be capable of circulating the ionic liquid L2 in the ionic liquid supply source 73 to and from the substrate support 20 through the ionic liquid supply port 71 and the ionic liquid discharge port 72.

The controller 2 processes a computer-executable instruction that causes the substrate processing apparatus 1 to execute various steps described in the present disclosure. The controller 2 can be configured to control each element of the substrate processing apparatus 1 so that various steps described herein are executed. In an embodiment, the substrate processing apparatus 1 may include a part or all of the controller 2. The controller 2 may include a processor 2a1, a storage 2a2, and a communication interface 2a3. The controller 2 is implemented by, for example, a computer 2a. The processor 2a1 can be configured to read a program from the storage 2a2, and execute the read program, thereby performing various operations. This program may be stored in the storage 2a2 in advance, or may be acquired through a medium when necessary. The acquired program is stored in the storage 2a2, and is read from the storage 2a2 and executed by the processor 2a1. The medium may be a storage medium of every kind which can be read by the computer 2a, or a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the substrate processing apparatus 1 through a local area network (LAN).

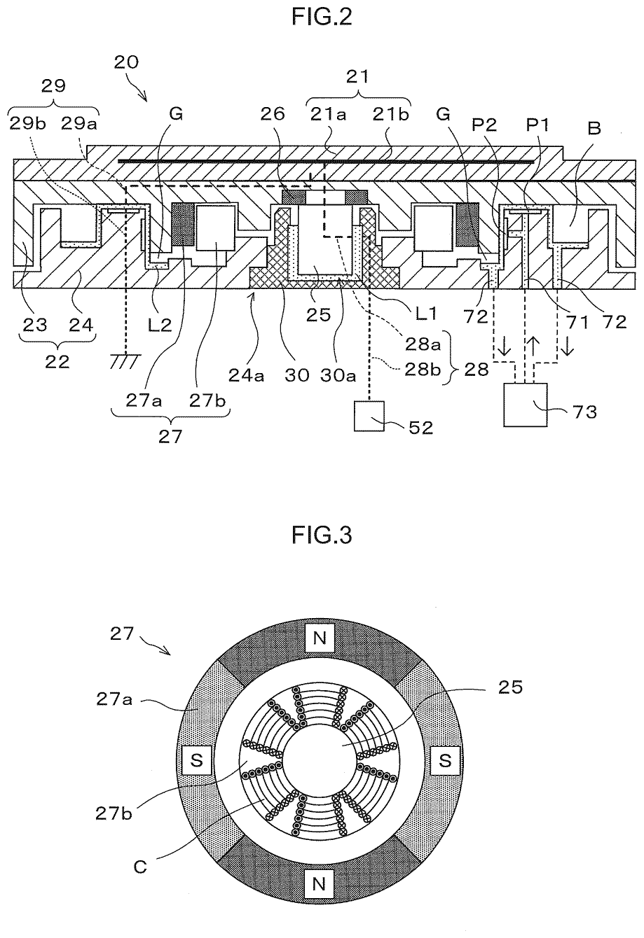

The substrate processing system according to the present embodiment is configured as described above, which is an example. Next, a detailed configuration of the substrate support 20 will be described with reference to the drawings. FIG. 2 is a sectional view schematically illustrating a detailed configuration of the substrate support 20.

As described above, the substrate support 20 includes the electrostatic chuck 21 and the base 22. The base 22 and the electrostatic chuck 21 are arranged by being stacked in the stated order from the side of the bottom surface of the processing chamber 10.

The electrostatic chuck 21 includes a ceramic member 21a and one or more electrodes 21b arranged in the ceramic member 21a. The ceramic member 21a has a substrate support surface. Therefore, one or more substrates W to be processed are placed on the upper surface of the electrostatic chuck 21 in the processing chamber 10.

As illustrated in FIG. 2, the base 22 includes a rotation stage 23 as a first stage and a fixation stage 24 as a second stage. The rotation stage 23 is arranged on the electrostatic chuck 21 side, that is, the upper side of the base 22, and the fixation stage 24 is arranged on the side of the bottom surface of the processing chamber 10, that is, on the lower side of the base 22. The fixation stage 24 is arranged so as not to be in mechanical contact with the rotation stage 23, that is, such that a gap G is formed between the fixation stage 24 and the rotation stage 23.

In the substrate support according to the technique of the present disclosure, the “electrostatic chuck 21” and the “rotation stage 23” may be collectively referred to as a “first stage”. Therefore, the first stage has a substrate support surface.

A rotation shaft 25 substantially coinciding with the center of the rotation stage 23 in plan view is connected to the lower part of the rotation stage 23 through an insulating component 26. The rotation shaft 25 is arranged such that the lower part thereof is immersed in a later-described ionic liquid L1 filling a later-described insulator 30 arranged at the central part of the fixation stage 24 in the lower part of the rotation stage 23.

An opening 24a is formed at a substantially central part of the fixation stage 24. In addition, the insulator 30 having a concave portion 30a in which the rotation shaft 25 is arranged is fitted in the opening 24a (on the inner side in the radial direction). Therefore, the insulator 30 has a substantially box shape which has an opening at the upper surface in sectional view. The inside of the concave portion 30a of the insulator 30 is filled with the ionic liquid L1 described later. Therefore, the ionic liquid L1 filling the concave portion 30a is electrically separated from the fixation stage 24 with the insulator 30 interposed therebetween. The rotation shaft 25 of the rotation stage 23 is arranged by being inserted into the concave portion 30a so as to be immersed in the ionic liquid L1.

In addition, the rotation mechanism 27 for rotating the rotation shaft 25 about a vertical axis is provided inside the base 22 of the substrate support 20. The rotation mechanism 27 for rotating the rotation stage 23 (electrostatic chuck 21) is arranged. Since the rotation shaft 25 is connected to the rotation stage 23 through the insulating component 26 as described above, the rotation stage 23 is configured to be capable of being rotated about the vertical axis together with the rotation shaft 25 by the rotation mechanism 27.

Therefore, in the present embodiment, the electrostatic chuck 21, the rotation stage 23, and the rotation shaft 25 are members on the rotation side, and the fixation stage 24 and the insulator 30 are members on the fixation side.

The rotation mechanism 27 may be a variable-speed mechanism capable of controlling the rotational speed. In an embodiment, as illustrated in FIG. 3, the rotation mechanism 27 includes a permanent magnet 27a as a rotor which is arranged on the rotation stage 23 belonging to the rotation side, and a motor 27b arranged on the fixation stage 24 belonging to the fixation side on the inner periphery side of the permanent magnet 27a. The permanent magnet 27a has a substantially circular ring shape in which N poles and S poles are alternately arranged in the circumferential direction. The motor 27b includes a plurality of coils C. As described above, the DC power supply 52 is coupled to the motor 27b, more specifically, each of the plurality of coils C. Therefore, in the present embodiment, the rotation mechanism 27 includes a so-called brush less (BL) DC motor which rotates the permanent magnet 27a in a non-contact manner using a magnetic flux generated by application of a voltage from the DC power supply 52 to the coil.

In the substrate support 20, a feeder wire 28 connected to the electrode 21b arranged in the electrostatic chuck 21 and a ground wire 29 are disposed. The feeder wire 28 includes a first feeder wire 28a disposed on the rotation side of the substrate support 20, and a second feeder wire 28b disposed on the fixation side. The ground wire 29 includes a first ground wire 29a disposed on the rotation side of the substrate support 20, and a second ground wire 29b disposed on the fixation side. Therefore, in the present embodiment, the first feeder wire 28a and the first ground wire 29a correspond to “rotation side wiring” in the technique of the present disclosure, and the second feeder wire 28b and the second ground wire 29b correspond to “wiring” in the technique of the present disclosure.

In the first feeder wire 28a, one end part is coupled to the electrode 21b, and the other end part is electrically coupled to the second feeder wire 28b. In the second feeder wire 28b, one end part is electrically coupled to the first feeder wire 28a, and the other end part is coupled to the DC power supply 52.

In the first ground wire 29a, one end part is coupled to the electrostatic chuck 21, and the other end part is electrically coupled to the second ground wire 29b. In the second ground wire 29b, one end part is electrically coupled to the first ground wire 29a, and the other end part is coupled to a ground potential, for example, the processing chamber 10.

In the present embodiment, the second feeder wire 28b is electrically coupled to the electrode 21b through the first feeder wire 28a, but the second feeder wire 28b may be directly coupled to the electrode 21b without the first feeder wire 28a. Therefore, the second feeder wire 28b is electrically coupled to the electrode 21b. Similarly, the second ground wire 29b may be electrically coupled to the electrostatic chuck 21 through the first ground wire 29a, or may be electrically coupled directly to the electrostatic chuck 21 without the first ground wire 29a.

Here, in the substrate support 20 according to the present embodiment, if the wiring on the rotation side (first feeder wire 28a and first ground wire 29a) and the wiring on the fixation side (second feeder wire 28b and second ground wire 29b) are mechanically contacted as in, for example, the slip ring mechanism described in Japanese Laid-open Patent Publication No. 2015-185757, this may cause generation of particles and wear of the wiring.

Thus, in the substrate support 20 according to the present disclosure, instead of mechanical contact between the wiring on the rotation side and the wiring on the fixation side, ionic liquids L1 and L2 are, respectively, interposed therebetween to electrically couple the wiring on the rotation side and the wiring on the fixation side.

The ionic liquid is an ionic compound that is liquid at ordinary temperature, and the ionic liquid is also called a salt in a molten state at ordinary temperature. The ionic liquid is characterized by, for example, having a vapor pressure of almost 0, and having non-volatility (not volatile either at high temperature or in vacuum). The ionic liquid includes positive ions (cations) and negative ions (anions).

Examples of the positive ion forming the ionic liquid include positive ions of pyridinium type, imidazolium type, ammonium type, pyrrolidinium type, piperidinium type and phosphonium type which contain nitrogen, and positive ions of phosphonium type which contain phosphorus. These positive ions contain an alkyl group [—(CH₂)ₙCH₃] as a side chain. Other examples of the positive ion forming the ionic liquid include those of morpholinium type and sulfonium type.

Examples of the positive ion of pyridinium type include, but are not limited to, C₂py⁺ represented by chemical formula (C1-1) and C₄py⁺ represented by chemical formula (C1-2).

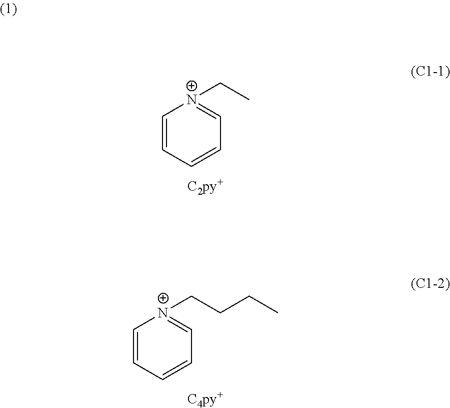

Examples of the positive ion of imidazolium type include, but are not limited to, C₂mim⁺ represented by chemical formula (C2-1), C₄mim⁺ represented by chemical formula (C2-2), C₆mim⁺ represented by chemical formula (C2-3), and C₈mim⁺ represented by chemical formula (C2-4).

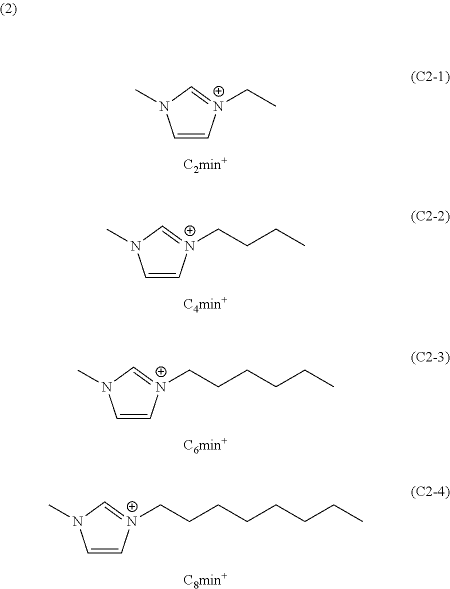

Examples of the positive ion of ammonium type include, but are not limited to, N_{3,1,1,1}⁺ represented by chemical formula (C3-1), N_{4,1,1,1}⁺ represented by chemical formula (C3-2), N_{6,1,1,1}⁺ represented by chemical formula (C3-3), N_{2,2,1,(2O1)}⁺ represented by chemical formula (C3-4), and Ch⁺ represented by chemical formula (C3-5).

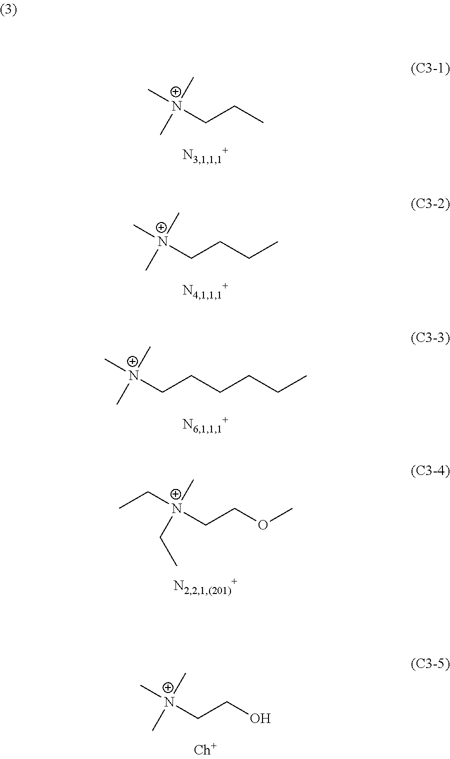

Examples of the positive ion of pyrrolidinium type include, but are not limited to, Pyr_{1,3}⁺ represented by chemical formula (C4-1), and Pyr_{1,4}⁺ represented by chemical formula (C4-2).

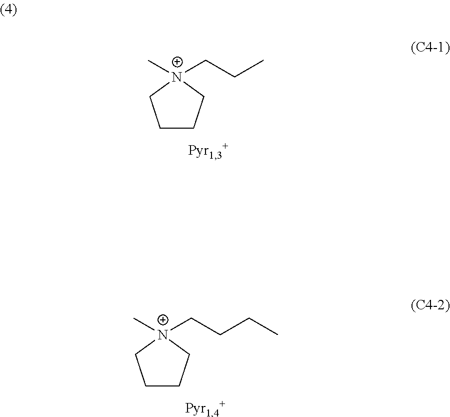

Examples of the positive ion of piperidinium type include, but are not limited to, Pip_{1,3}⁺ represented by chemical formula (C5-1), and Pip_{1,4}⁺ represented by chemical formula (C5-2).

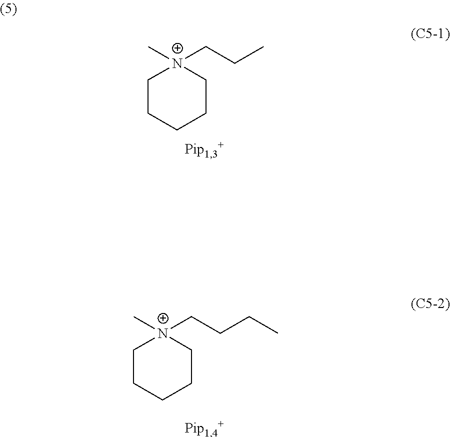

Examples of the positive ion of phosphonium type include, but are not limited to, P_{5,2,2,2}⁺ represented by chemical formula (C6-1), and P_{6,6,6,14}⁺ represented by chemical formula (C6-2).

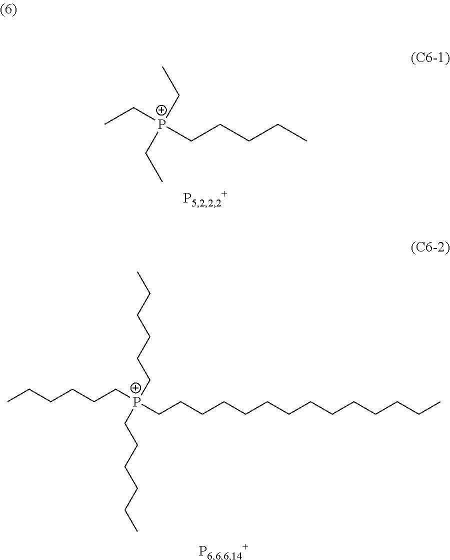 [SMILES: CCCCC[P+](CC)(CC)CC ; CCCCCCCCCCCCCC[P+](CCCCCC)(CCCCCC)CCCCCC]

Examples of the negative ion forming the ionic liquid include, but are not limited to, TfO⁻ represented by chemical formula (A1), Tf2N⁻ (TFSA⁻) represented by chemical formula (A2), Tf3C⁻ represented by chemical formula (A3), FSA⁻ represented by chemical formula (A4), CH₃COO⁻ represented by chemical formula (A5), CF₃COO⁻ represented by chemical formula (A6), BF4⁻ represented by chemical formula (A7), PF₆⁻ represented by chemical formula (A8), (CN)₂N-represented by chemical formula (A9), AlCl₄⁻ represented by chemical formula (A10), and Al₂Cl₇⁻ represented by chemical formula (A11). Other examples of the negative ion forming the ionic liquid include PF₆⁻ and Cl⁻.

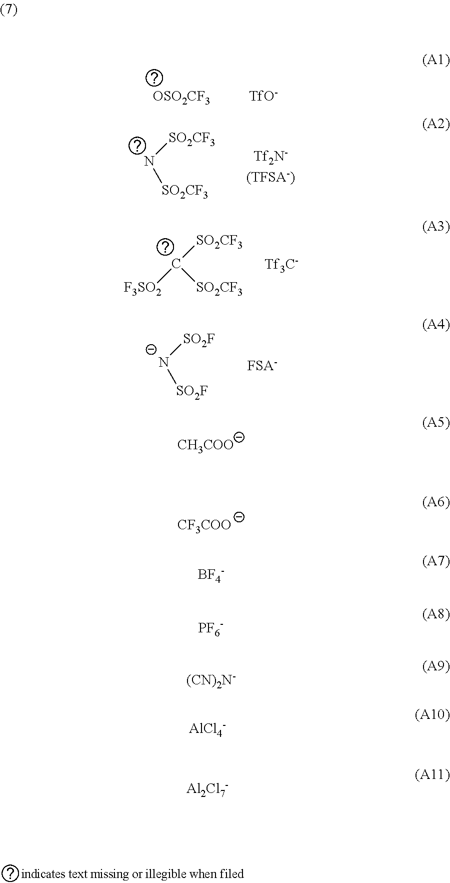

Specific examples of the ionic liquid include N,N-diethyl-N-methyl-N-(2-methoxyethyl)ammoniumbis(trifluoromethanesulfonyl)imide (DEME·TFSA), and 1-ethyl-3-methylimidazolium dicyanamide.

See FIG. 2 again.

As illustrated in FIG. 2, the ionic liquid L1 fills the gap between the rotation side member and the fixation side member at the central part of the substrate support 20, more specifically, the inside of the concave portion 30a of the insulator 30. The filling amount of the ionic liquid L1 is determined such that at least the entire cross-section of the first feeder wire 28a exposed on the rotation side and the entire cross-section of the second feeder wire 28b exposed on the fixation side are immersed in the ionic liquid L1. Therefore, the disposition route of the feeder wire 28 (the power feeding route to the electrode 21b) is determined so as to interpose the ionic liquid L1 at least between the rotation side member and the fixation side member of the substrate support 20.

As illustrated in FIG. 2, the ionic liquid L2 is supplied between the rotation side member and the fixation side member at the outer peripheral part of the substrate support 20, more specifically, to the gap G between the rotation stage 23 and the fixation stage 24. As illustrated in FIG. 2, the ionic liquid L2 is configured to be capable of circulating to and from, for example, the ionic liquid supply source 73 arranged outside the processing chamber 10, through the ionic liquid supply port 71 formed on the lower surface side of the fixation stage 24, and the ionic liquid discharge port 72. Therefore, the ionic liquid L2 circulates through the ionic liquid supply source 73, the ionic liquid supply port 71, the gap G in the outer peripheral part of the substrate support 20, and the ionic liquid discharge port 72 in the stated order. The disposition route of the ground wire 29 (a neutralization route from the electrostatic chuck 21) is determined so as to interpose the ionic liquid L2 at least between the rotation side member and the fixation side member of the substrate support 20. A buffer space B capable of temporarily storing the ionic liquid L2 may be formed inside the substrate support 20, more specifically, between the rotation stage 23 and the fixation stage 24 so that the ionic liquid L2 discharged from the ionic liquid discharge port 72 is prevented from leaking into the processing chamber 10.

As the position of supplying the ionic liquid L2 to the gap G of the substrate support 20, at least two positions, one of which is a first supply position P1 where the ionic liquid L2 is supplied from below (in the vertical direction) to the rotation stage 23 and the other of which is a second supply position P2 where the ionic liquid L2 is supplied from the side (in the horizontal direction) to the rotation stage 23, are set as illustrated in FIG. 2. In an example, each of the first supply position P1 and the second supply position P2 is a ring-shaped supply port formed over the entire circumference of the fixation stage 24 in plan view.

In the substrate support 20 according to the present embodiment, the gap G is formed between the rotation stage 23 and the fixation stage 24 to prevent mechanical contact between the rotation stage 23 and the fixation stage 24 as described above, but for example, the position of the rotation stage 23 may change due to an axial shift caused by rotation of the rotation stage 23, self weight or the like, leading to occurrence of mechanical contact with the fixation stage 24.

Thus, in the substrate support 20 according to the present disclosure, the ionic liquid L2 is supplied to the rotation stage 23 in at least two directions, one of which is a vertical direction and the other of which is a horizontal direction as described above. As a result, stress acting on the rotation stage 23 (the force of collision of the ionic liquid L2 against the rotation stage 23) due to supply of the ionic liquid L2 maintains the posture of the rotation stage 23, so that mechanical contact between the rotation stage 23 and the fixation stage 24 can be appropriately suppressed.

In the present embodiment, in the substrate support 20, the concave portion 30a is filled with the ionic liquid L1 in advance, and the ionic liquid L2 is circulated to and from the ionic liquid supply source 73. However, for example, as long as mechanical contact between the rotation stage 23 and the fixation stage 24 which is caused by rotation can be appropriately suppressed, the substrate support 20 may be filled with the ionic liquid L2 in advance instead of circulating the ionic liquid L2 to and from the ionic liquid supply source 73. Alternatively, the ionic liquid L1 may be circulated to and from the ionic liquid supply source 73. Therefore, the ionic liquid supply port 71 and the ionic liquid discharge port 72 may be formed on the side of the central part of the substrate support 20 so as to circulate the ionic liquid L1.

The substrate support 20 according to the present embodiment is configured as described above.

As described above, in the substrate support 20 according to the present embodiment, the first wiring (electrode) on the rotation side and the second wiring on the fixation side of the substrate support 20 can be electrically coupled through an ionic liquid without mechanical contact that occurs in a conventional slip ring mechanism, and therefore, generation of abrasion powder in power feeding to the electrostatic chuck 21 can be suppressed. This suppresses attachment of abrasion powder to the substrate W to be processed and the electrostatic chuck 21, so that it is possible to suppress occurrence of failure in substrate processing which is caused by the abrasion powder.

In addition, since there is no mechanical contact between the first wiring on the rotation side and the second wiring on the fixation side of the substrate support 20 as described above, abrasion (wear) of the wiring is suppressed. As a result, the frequency of maintenance of a semiconductor production apparatus which is associated with the replacement of the wiring disposed in the substrate support 20 can be decreased to reduce the downtime of the semiconductor production apparatus.

In addition, an ionic liquid has been commonly used as a lubricating oil for improving the lubricity of a contact portion of metal. Therefore, by interposing the ionic liquid between the rotation stage 23 and the fixation stage 24 in the substrate support 20 as described above, rotation of the rotation stage 23 with respect to the fixation stage 24 can be smoothly performed, and the rotation of the substrate W during substrate processing can be precisely controlled.

Further, it is known that in general, an ionic liquid has low volatility and exists as a liquid in vacuum. Therefore, the ionic liquids L1 and L2 do not volatilize inside the processing chamber 10 for processing the substrate W under vacuum, and can electrically connect the first feeder wire 28a and the second feeder wire 28b, and the first ground wire 29a and the second ground wire 29b appropriately to perform power feeding to the electrode 21b and neutralization of the electrostatic chuck 21.

Further, in the substrate support 20 according to the present embodiment, the rotation mechanism 27 for rotating the rotation stage 23 (electrostatic chuck 21) is arranged inside the substrate support 20, and is not required to be arranged on the outside (lower part) of the processing chamber 10. Therefore, a mechanism in which generation of particles is suppressed to a greater degree as compared to a conventional slip ring mechanism can be entirely introduced into the processing chamber 10, so that it is not necessary to provide the processing chamber 10 with a vacuum seal or a magnetic seal for inserting the rotation shaft 25 into the processing chamber 10, and it is possible to achieve space saving in the longitudinal direction in the substrate processing apparatus 1.

In the above embodiment, a case where the substrate processing apparatus includes a plasma producer for inductively coupled plasma (ICP) has been described as an example. However, the configuration of the plasma producer is not limited thereto, and may be for capacitively coupled plasma (CCP), electron-cyclotron-resonance plasma (ECR plasma), helicon wave plasma (HWP), surface wave plasma (SWP), or the like. In addition, various types of plasma producers including an alternating current (AC) plasma producer and a direct current (DC) plasma producer may be used. In an embodiment, the frequency of the AC signal (AC power) used in the AC plasma producer is within the range of 100 kHz to 10 GHZ. Therefore, the AC signal includes a radio frequency (RF) signal and a microwave signal. In an embodiment, the frequency of an RF signal is within the range of 100 kHz to 150 MHz.

In addition, in the above embodiment, a case where the substrate processing apparatus is a vacuum processing module that performs plasma processing on the substrate W under vacuum has been described as an example. However, the configuration of the substrate processing apparatus is not limited thereto. For example, other processing as an alternative to plasma processing may be performed on the substrate W under vacuum. Alternatively, the substrate W may be processed under atmospheric pressure instead of under vacuum.

In any of these cases, by having a configuration in which electric power can be supplied between the rotation side member and the fixation side member through an ionic liquid, instead of a conventional slip ring mechanism, generation of abrasion powder can be suppressed to inhibit occurrence of failure of substrate processing, and the frequency of replacement of the mechanism can be decreased to reduce the time involved in maintenance.

Further, by providing a rotation mechanism for rotating the rotation stage inside the processing chamber, more specifically, inside the substrate support, space saving in the longitudinal direction in the substrate processing apparatus can be achieved to a greater degree as compared to a case where the rotation mechanism is arranged in the lower space of the processing chamber.

In the above embodiment, a case where the electric power supply destination inside the substrate support is the adsorption electrode (so-called a chuck electrode) arranged in the electrostatic chuck has been described as an example. However, the electrode that is supplied with electric power using a method according to the technique of the present disclosure is not limited to such the adsorption electrode, and any electrode can be supplied with electric power as long as it is supplied with electric power in a state of being sandwiched between the rotation side and the fixation side. Specifically, for example, when the substrate W on a susceptor needs to be heated while being rotated, a heater electrode arranged in the susceptor may be supplied with electric power by the method according to the present disclosure. Therefore, in the technique according to the present disclosure, the “electrode” that is supplied with electric power can be selected from at least one of an adsorption electrode and a heater electrode.

It should be considered that the embodiments disclosed herein are illustrative in all respects, and are not restrictive. In the above embodiments, omissions, replacements or changes may be made in various forms without departing from the appended claims and the spirit thereof. For example, the constitutional features of the above embodiments can be arbitrarily combined. From the arbitrary combination, the action and the effect of each constitutional feature of the combination can be obtained as a matter of course, and other actions and other effects that are obvious to those skilled in the art from the description of the present specification can be obtained.

In addition, the effects described in the present specification are merely illustrative or exemplary, and are not restrictive. That is, the technique according to the present disclosure can exhibit, in addition to the effects or instead of the effects, other effects that are obvious to those skilled in the art from the description of the present specification.

The following configuration examples are also within the technical scope of the present disclosure.

According to the present disclosure, in a substrate support including a rotation mechanism, an electrode provided inside the substrate support can be supplied with electric power without mechanical contact between the rotation side and the fixation side.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

The technical scope of this disclosure also includes the following example configurations.

(1) A substrate support comprising a rotation side member and a fixation side member, wherein the rotation side member includes a first stage having a support surface that supports a substrate, and at least one electrode arranged in the first stage, the fixation side member includes a second stage arranged so as to form a gap between the second stage and the first stage below the first stage, and an electric wire arranged in the second stage, and the electrode and the electric wire are electrically coupled through an ionic liquid in the gap.

(2) The substrate support according to (1), which is arranged inside a vacuum processing chamber in which an inside can be maintained in a vacuum state.

(3) The substrate support according to (1) or (2), wherein the gap at a central part of the substrate support is filled with the ionic liquid.

(4) The substrate support according to any one of (1) to (3), wherein the ionic liquid is further supplied to the gap at an outer peripheral part of the substrate support.

(5) The substrate support according to any one of (1) to (4), further comprising a supply port for supplying the ionic liquid to the gap, and a discharge port for discharging the ionic liquid from the gap.

(6) The substrate support according to (5), wherein the ionic liquid is supplied from a side of the fixation side member to a side of the rotation side member in at least two directions, one of which is a horizontal direction and the other of which is a vertical direction.

(7) A substrate support according to any one of (1) to (6), wherein a rotation mechanism that rotates the rotation side member includes a permanent magnet arranged in the rotation side member, and a motor that is arranged in the fixation side member, and includes a plurality of coils.

(8) The substrate support according to (7), wherein the permanent magnet is arranged so as to surround a periphery of the motor.

(9) The substrate support according to any one of (1) to (8), further comprising rotation side wiring that is arranged in the rotation side member, and electrically couples the electrode and the electric wire through the ionic liquid.

(10) The substrate support according to any one of (1) to (9), wherein the ionic liquid is selected from at least one of N,N-diethyl-N-methyl-N-(2-methoxyethyl)ammoniumbis(trifluoromethanesulfonyl)imide, or 1-ethyl-3-methylimidazolium dicyanamide.

(11) A substrate processing apparatus for processing a substrate, comprising: a processing chamber;
a substrate support including a rotation side member and a fixation side member, wherein the rotation side member includes a first stage having a support surface that supports a substrate, and at least one electrode arranged in the first stage, the fixation side member includes a second stage arranged so as to form a gap between the second stage and the first stage below the first stage, and an electric wire arranged in the second stage, and the electrode and the electric wire are electrically coupled through an ionic liquid in the gap; and a power supply that supplies electric power to the electrode.

(12) The substrate processing apparatus according to (11), wherein the processing chamber is a vacuum processing chamber that performs processing on the substrate under vacuum.

(13) The substrate processing apparatus according to (11) or (12), wherein a rotation mechanism that rotates the rotation side member is arranged in the processing chamber.

(14) The substrate processing apparatus according to any one of (11) to (13), wherein the rotation mechanism includes a permanent magnet arranged in the rotation side member, and a motor that is arranged in the fixation side member, and includes a plurality of coils.

(15) The substrate processing apparatus according to any one of (11) to (14), wherein the substrate support includes a supply port for supplying the ionic liquid to the gap, and a discharge port for discharging the ionic liquid from the gap.

(16) The substrate processing apparatus according to any one of (11) to (15), further comprising rotation side wiring that is arranged in the rotation side member, and electrically connects the electrode and the electric wire through the ionic liquid.

(17) A method for supplying electric power to at least one electrode arranged in a rotation side member in a substrate support including the rotation side member and a fixation side member, wherein the substrate support includes an electric wire arranged in the fixation side member, a gap is formed between the rotation side member and the fixation side member, and an ionic liquid is supplied to the gap, and the electrode and the electric wire are electrically coupled through the ionic liquid.

(18) The method for supplying electric power according to (17), wherein the ionic liquid is supplied from a side of the fixation side member to a side of the rotation side member in at least two directions, one of which is a horizontal direction and the other of which is a vertical direction.

(19) The method for supplying electric power according to (17) or (18), wherein a rotation mechanism that rotates the rotation side member includes a permanent magnet arranged in the rotation side member, and a motor that is arranged in the fixation side member, and includes a plurality of coils, and the permanent magnet is rotated in a non-contact manner using a magnetic field produced by the coils.

What is claimed is:

1. A substrate support comprising a rotation side member and a fixation side member, wherein
the rotation side member includes
a first stage having a support surface that supports a substrate, and
at least one electrode arranged in the first stage,
the fixation side member includes
a second stage arranged so as to form a gap between the second stage and the first stage below the first stage, and
an electric wire arranged in the second stage, and
the electrode and the electric wire are electrically coupled through an ionic liquid in the gap.

2. The substrate support according to claim 1, which is arranged inside a vacuum processing chamber in which an inside can be maintained in a vacuum state.

3. The substrate support according to claim 1, wherein the gap at a central part of the substrate support is filled with the ionic liquid.

4. The substrate support according to claim 3, wherein the ionic liquid is further supplied to the gap at an outer peripheral part of the substrate support.

5. The substrate support according to claim 1, further comprising a supply port for supplying the ionic liquid to the gap, and a discharge port for discharging the ionic liquid from the gap.

6. The substrate support according to claim 5, wherein the ionic liquid is supplied from a side of the fixation side member to a side of the rotation side member in at least two directions, one of which is a horizontal direction and the other of which is a vertical direction.

7. A substrate support according to claim 1, wherein a rotation mechanism that rotates the rotation side member includes
a permanent magnet arranged in the rotation side member, and
a motor that is arranged in the fixation side member, and includes a plurality of coils.

8. The substrate support according to claim 7, wherein the permanent magnet is arranged so as to surround a periphery of the motor.

9. The substrate support according to claim 1, further comprising rotation side wiring that is arranged in the rotation side member, and electrically couples the electrode and the electric wire through the ionic liquid.

10. The substrate support according to claim 1, wherein the ionic liquid is selected from at least one of N,N-diethyl-N-methyl-N-(2-methoxyethyl)ammoniumbis(trifluoromethanesulfonyl)imide, or 1-ethyl-3-methylimidazolium dicyanamide.

11. A substrate processing apparatus for processing a substrate, comprising:
a processing chamber;
a substrate support including a rotation side member and a fixation side member, wherein
the rotation side member includes
a first stage having a support surface that supports a substrate, and
at least one electrode arranged in the first stage,
the fixation side member includes
a second stage arranged so as to form a gap between the second stage and the first stage below the first stage, and
an electric wire arranged in the second stage, and
the electrode and the electric wire are electrically coupled through an ionic liquid in the gap; and
a power supply that supplies electric power to the electrode.

12. The substrate processing apparatus according to claim 11, wherein the processing chamber is a vacuum processing chamber that performs processing on the substrate under vacuum.

13. The substrate processing apparatus according to claim 11, wherein a rotation mechanism that rotates the rotation side member is arranged in the processing chamber.

14. The substrate processing apparatus according to claim 13, wherein the rotation mechanism includes
a permanent magnet arranged in the rotation side member, and
a motor that is arranged in the fixation side member, and includes a plurality of coils.

15. The substrate processing apparatus according to claim 11, wherein the substrate support includes a supply port for supplying the ionic liquid to the gap, and a discharge port for discharging the ionic liquid from the gap.

16. The substrate processing apparatus according to claim 11, further comprising rotation side wiring that is arranged in the rotation side member, and electrically connects the electrode and the electric wire through the ionic liquid.

17. A method for supplying electric power to at least one electrode arranged in a rotation side member in a substrate support including the rotation side member and a fixation side member, wherein
the substrate support includes
an electric wire arranged in the fixation side member,
a gap is formed between the rotation side member and the fixation side member, and
an ionic liquid is supplied to the gap, and the electrode and the electric wire are electrically coupled through the ionic liquid.

18. The method for supplying electric power according to claim 17, wherein the ionic liquid is supplied from a side of the fixation side member to a side of the rotation side member in at least two directions, one of which is a horizontal direction and the other of which is a vertical direction.

19. The method for supplying electric power according to claim 17, wherein a rotation mechanism that rotates the rotation side member includes
a permanent magnet arranged in the rotation side member, and
a motor that is arranged in the fixation side member, and includes a plurality of coils, and
the permanent magnet is rotated in a non-contact manner using a magnetic field produced by the coils.
